(19) United States
(12) Patent Application Publication
(10) Pub. No.: US 2016/0104652 A1
(43) Pub. Date: Apr. 14, 2016

(54) PACKAGE STRUCTURE AND METHOD OF FABRICATING THE SAME

(71) Applicant: PHOENIX PIONEER TECHNOLOGY CO., LTD, Hsinchu County (TW)

(72) Inventors: Shih-Ping Hsu, Hsinchu County (TW); Chih-Wen Liu, Hsinchu County (TW); Tang-I Wu, Hsinchu County (TW); Shu-Wei Hu, Hsinchu County (TW)

(21) Appl. No.: 14/684,574

(22) Filed: Apr. 13, 2015

(30) Foreign Application Priority Data
Oct. 9, 2014 (TW) 1031135160

(51) Int. Cl. H01L 23/31; H01L 21/288; H01L 23/528; H01L 21/683; H01L 21/56; H01L 25/16; H01L 21/768

(52) U.S. Cl. CPC H01L 23/3107; H01L 25/16; H01L 21/2885; H01L 21/768; H01L 21/6835; H01L 21/568; H01L 23/528; H01L 2221/68359

(57) ABSTRACT

A method for fabricating a package structure is provided, which includes the steps of: forming a wiring layer on a carrier by electroplating; disposing at least one electronic component on the wiring layer; forming on the carrier an insulating layer that encapsulates the wiring layer and the electronic component; and removing the carrier. With the single wiring layer having one surface electrically connected the at least one electronic component and the other surface electrically connected to a plurality of conductive elements, the package structure has a signal transmission path that is shortened.

### BACKGROUND OF THE INVENTION

1. Field of the Invention

The present invention relates to package structures, and, more particularly, to a package structure having a single wiring layer and a method of fabricating the same.

2. Description of Related Art

Along with the progress of semiconductor packaging technologies, various package types, such as ball grid array (BGA) packages, quad flat packages (QFPs) and quad flat non-leaded (QFN) packages, have been developed for semiconductor devices. These packages can be applied in smart phones, tablets, networks, laptops and so on.

FIG. 1A is a schematic cross-sectional view of a conventional QFP structure 1. Referring to FIG. 1A, the QFP structure 1 has: a carrier 10; a plurality of leads 11 formed around a periphery of the carrier 10; an electronic component 12 attached to the carrier 10 and electrically connected to the leads 11 through a plurality of bonding wires 120; and an encapsulant 13 encapsulating the electronic components 12, the carrier 10, the bonding wires 120 and the leads 11. The leads 11 protrude from the encapsulant 13.

However, the carrier 10 and the leads 11 of the QFP structure 1 generally come from a lead frame, the arrangement of which limits trace routing. That is, the design of circuits and connections is limited. For example, in a conventional lead frame, a row of leads 11 have a total length of 400 um, and the carrier 10 has a length of 125 um, which limit the I/O count and pitch.

Further, the fixed size of the lead frame and the loop of the bonding wires 120 cause the QFP structure 1 to be thick and difficult to be thinned.

Furthermore, limited by the design of the lead frame, the QFP structure 1 has a small number of leads 11 and cannot meet the requirements of high I/O count and small thickness.

Although a metal board can be used to replace the lead frame and etched to form wiring layers, fine-pitch traces cannot be formed due to the limitation of etching machines. That is, it is not possible to form traces having a width/pitch below 30/30 um. As such, the overall structure cannot meet the requirement of small thickness, and warpage easily occurs to the overall structure.

FIG. 1B is a schematic cross-sectional view of a conventional BGA package structure 1′. The package structure 1′ has: a carrier 10′ having wiring layers 11a, 11b formed on upper and lower sides 10a, 10b thereof, respectively; an electronic component 12 disposed on the upper side 10a of the carrier 10′ and electrically connected to the wiring layer 11a through a plurality of conductive bumps 120′; an underfill 13 encapsulating the conductive elements 120′; and a plurality of conductive elements 14 such as solder balls formed on the wiring layer 11b of the lower side 10b of the carrier 10′ for external connection. Further, a plurality of conductive posts 100 are formed in the carrier 10′ and electrically connected to the wiring layers 11a, 11b. The electronic component 12 is electrically connected to the carrier 10′ through wire bonding or in a flip-chip manner. Compared with the QFP structure, the packaging substrate of the BGA package structure 1′ has a higher I/O count per unit area, and, as such, meets the requirement of a highly integrated chip.

However, during high-frequency or high-speed operation, a long signal transmission path along the conductive elements 14, the wiring layers 11a, 11b and the conductive posts 100 adversely affects the electrical performance of the package structure 1′.

Further, since the package structure 1′ has at least two wiring layers 11a, 11b, and the conductive posts 100 are electrically connected to the wiring layers 11a, 11b, the overall structure is quite thick and difficult to be thinned. Further, processes such as hole drilling and electroplating processes are required to form the wiring layers 11a, 11b and the conductive posts 100, which increase the fabrication cost.

Furthermore, since the package structure 1′ requires a lot of connection interfaces between the conductive elements 14, the wiring layers 11a, 11b and the conductive posts 100, and the layers of the carrier 10′ need to be made of different materials, the fabrication cost is further increased.

In addition, warpage easily occurs to the carrier 10′ due to a coefficient of thermal expansion (CTE) mismatch between the layers of different materials.

Therefore, there is a need to provide a package structure and a method of fabricating the same, so as to overcome the above-described drawbacks.

### SUMMARY OF THE INVENTION

In view of the above-described drawbacks, the present invention provides a package structure, which comprises: an insulating layer having a first surface and a second surface opposite to the first surface; a wiring layer formed in the insulating layer by electroplating and having a surface exposed from the first surface of the insulating layer; and at least one electronic component embedded in the insulating layer and electrically connected to the wiring layer.

The present invention further provides a method for fabricating a package structure, which comprises the steps of: forming a wiring layer on a carrier by electroplating; disposing at least one electronic component on the wiring layer, and electrically connecting the electronic component to the wiring layer; forming on the carrier an insulating layer that encapsulates the wiring layer and the electronic component and a first surface bonded to the carrier and a second surface opposite to the first surface; and removing the carrier to expose the wiring layer and the first surface of the insulating layer.

Therefore, by providing a single wiring layer having one surface electrically connected to an electronic component and the other surface electrically connected to a plurality of conductive elements such as solder balls, the present invention has a signal transmission path that is shortened, the signal loss is reduced, and the electrical performance is improved.

Further, since only one wiring layer is formed and the conventional conductive posts or conductive through holes are dispensed, the thickness of the package structure is greatly reduced, and the fabrication cost is significantly decreased.

Furthermore, using the opposite surfaces of the single wiring layer as connection interfaces and using a simple carrier in the fabrication process, the fabrication cost is reduced.

In addition, by removing the carrier, the present invention avoids warpage of the package structure.

### BRIEF DESCRIPTION OF DRAWINGS

FIG. 1A is a cross-sectional schematic view of a conventional QFP package structure;

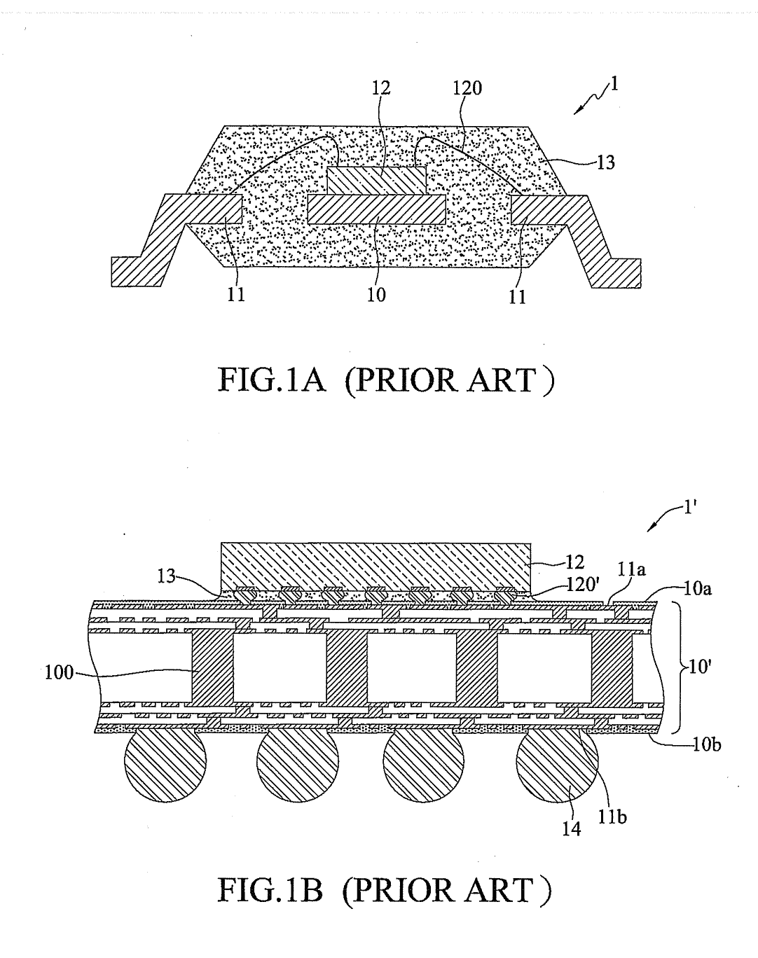

FIG. 1B is a cross-sectional schematic view of a conventional BGA package structure; and

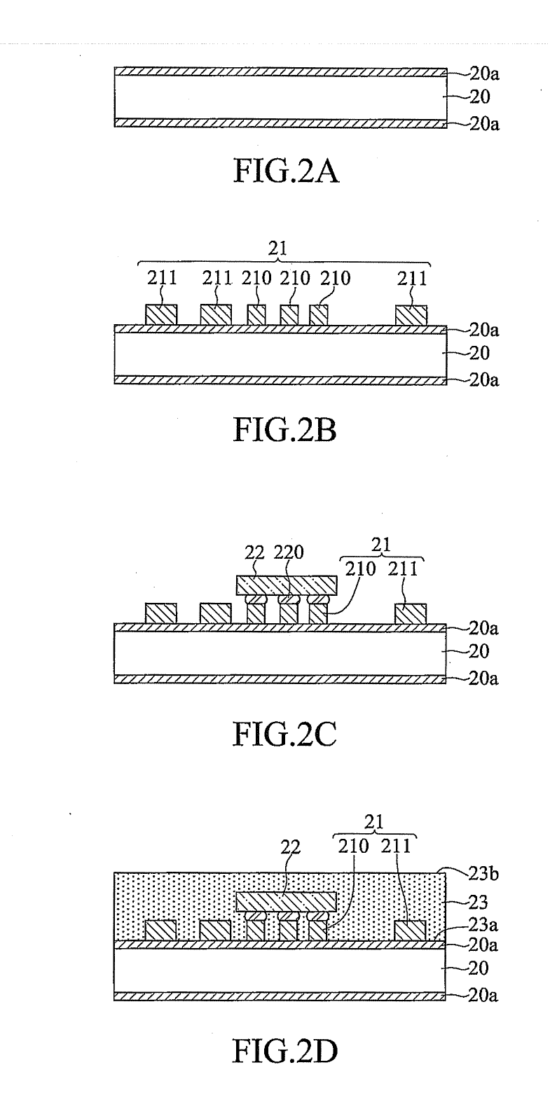

FIGS. 2A-2F are cross-sectional views showing a method of fabricating a package structure according to a first embodiment present invention; wherein FIGS. 2E′ and 2F′ are different examples of FIGS. 2E and 2F, respectively.

FIG. 3 is a cross-sectional schematic view showing a method of fabricating a package structure according to a second embodiment of the present invention; wherein FIG. 3′ is a different example of FIG. 3.

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms such as “upper”, “lower”, “first”, “second”, “one” etc. are merely for illustrative purposes and should not be construed to limit the scope of the present invention.

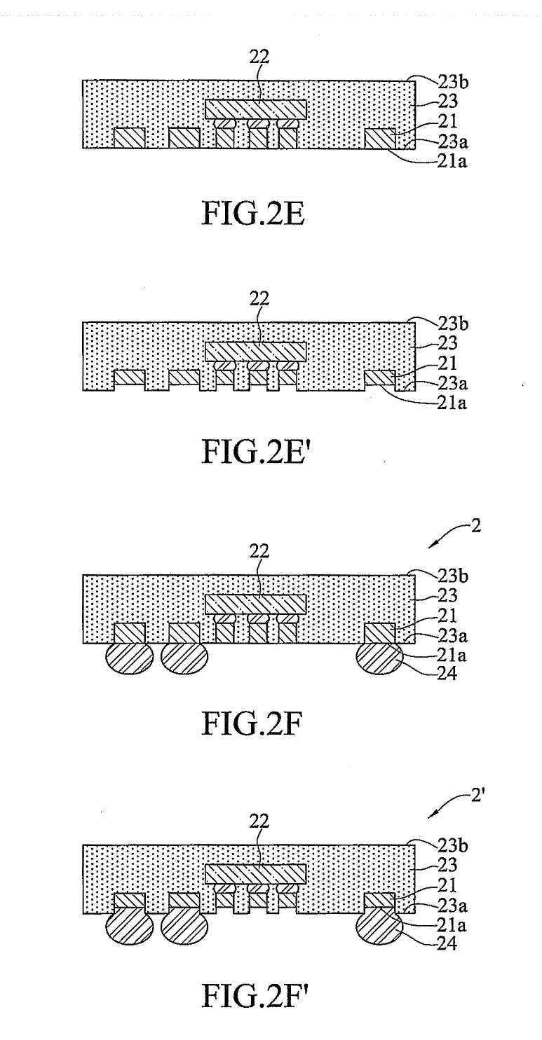

FIGS. 2A to 2F are schematic cross-sectional views showing a method of fabricating a package structure 2, 2′ of a first embodiment according to the present invention.

Referring to FIGS. 2A and 2B, a wiring layer 21 is formed on a carrier 20 by electroplating or deposition.

In an embodiment, the carrier 20 is a copper clad laminate having a metal layer 20a made of a copper-containing material formed on two opposite surfaces thereof.

The wiring layer 21 has a plurality of conductive pads 210 and a plurality of conductive traces 211.

Through electroplating or deposition, the wiring layer 21 can be routed according to the practical need so as to achieve fine-pitch traces having a width/pitch below 30/30 um.

Further, there is no limit on the design of circuits and connections. For example, if the conductive pads 210 have a total length of 400 um, they can be arranged in two rows, while only one row of leads can be provided in the conventional lead frame.

In addition, the number of the conductive pads 210 can be increased according to the practical need.

Referring to FIG. 2C, an electronic component 22 is disposed on and electrically connected to the wiring layer 21.

In an embodiment, the electronic component 22 is an active element such as a semiconductor element (for example, a chip), a passive element such as a resistor, a capacitor or an inductor, or a combination thereof.

The electronic component 22 is disposed on the wiring layer 21 in a flip-chip manner and electrically connected to the conductive pads 210 through a plurality of conductive bumps 220.

In other embodiments, the electronic component 22 is electrically connected to the conductive pads 210 through a plurality of bonding wires (not shown).

Referring to FIG. 2D, an insulating layer 23 is formed on the carrier 20 and encapsulates the wiring layer 21 and the electronic component 22. The insulating layer 23 has opposite first and second surfaces 23a, 23b and is bonded to the carrier 20 via the first surface 23a thereof.

In an embodiment, the insulating layer 23 is formed on the carrier 20 by molding, coating or laminating, and the insulating layer 23 is made of a molding compound, a primer, or a dielectric material such as an epoxy resin.

In another embodiment, an upper surface of the electronic component 22 is exposed from the second surface 23b of the insulating layer 23.

Further, the conductive bumps 220 can be encapsulated by an underfill (not shown) first, and then the insulating layer 23 is formed.

Referring to FIG. 2E, the carrier 20 is removed to expose a surface 21a of the wiring layer 21 and the first surface 23a of the insulating layer 23.

In an embodiment, the exposed surface 21a of the wiring layer 21 serves as ball mounting pads, and is flush with the first surface 23a of the insulating layer 23.

In another embodiment, referring to FIG. 2E′, if the metal layer 20a is removed by etching, the wiring layer 21 will be slightly etched. As such, the exposed surface 21a of the wiring layer 21 is slightly recessed relative to the first surface 23a of the insulating layer 23.

Referring to FIGS. 2F and 2F′, a plurality of conductive elements 24 such as solder balls are formed on the first surface 23a of the insulating layer 23 and electrically connected to the wiring layer 21. As such, an electronic device (not shown) can be stacked on and electrically connected to the package structure through the conductive elements 24.

In an embodiment, the conductive elements 24 are bonded to the exposed surface 21a of the wiring layer 21.

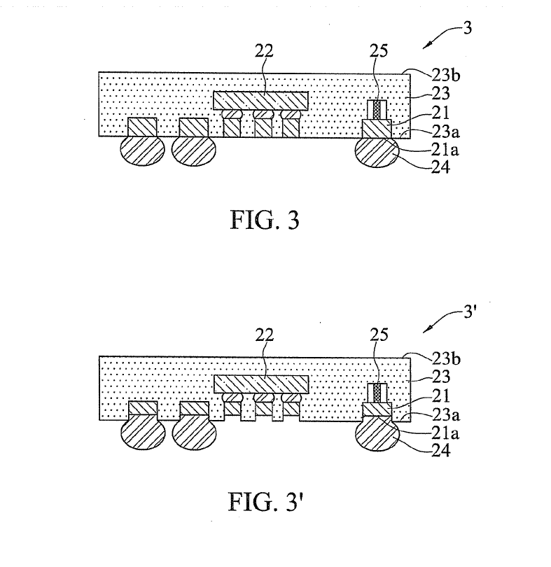

As shown in FIGS. 3 and 3′, in the fabricating process shown in FIG. 2C, two independent electronic components 22 and 25 are disposed on the wiring layer 21 that are electrically isolated from each other are electrically connected to the wiring layer 21.

In an embodiment, the electronic components 22,25 are active elements such as semiconductor elements (for example, chips), passive elements such as resistors, capacitors or an inductors, or a combination thereof, wherein one electronic component 22 is an active element, and the other element 25 is a passive element.

Further, in another embodiment, the electronic components 22 and 25 may be of the same types. For example, the electronic components 22 and 25 may both be active elements or passive elements. As such, it is freely routable and thus the electronic component 25 can be disposed using a surface mount technology (SMT)

In addition, the electronic component 22 used as an active element, for example, is bonded and electrically connected to the conductive pads 210 via a plurality of conductive bumps 220 in a flip chip manner, and the electronic component 25 used as a passive element, for example, is bonded and electrically connected to the conductive pads 210 using a surface mount technology.

Furthermore, in other embodiments, the electronic component 22 used as an active element can be electrically connected with the conductive pads 210 by a plurality of bonding wires (not shown).

According to the method of fabricating the package structures 2, 2′, 3 and 3′ according to the present invention, a single wiring layer 21 is provided with one surface electrically connected the electronic component 22, 25 and the other surface electrically connected to the conductive elements 24. As such, the signal transmission path is shortened, the signal loss is reduced, and the electrical performance is improved.

Further, since only one wiring layer 21 is formed and the conventional conductive posts are dispensed with, the thickness of the package structures 2, 2′, 3 and 3′ is greatly reduced, and the fabrication cost is significantly decreased.

Furthermore, using the opposite surfaces of the single wiring layer 21 as connection interfaces (for example, the conductive pads 210 and the exposed surface 21a) and using the simple carrier 20 (for example, a copper clad laminate) in the fabrication process, the fabrication cost is reduced.

In addition, by removing the carrier 20, the present invention avoids warpage of the package structures 2, 2′, 3 and 3′.

The present invention further provides package structures 2, 2′, 3 and 3′, each of which has: an insulating layer 23 having a first surface 23a and a second surface 23b opposite to the first surface 23a; a wiring layer 21 formed in the insulating layer 23 by electroplating and having a surface 21a exposed from the first surface 23a of the insulating layer 23; and at least one electronic component 22, 25 embedded in the insulating layer 23 and electrically connected to the wiring layer 21.

The insulating layer 23 can be made of a molding compound, a primer or a dielectric material.

The wiring layer 21 can be embedded in the first surface 23a of the insulating layer 23, and the exposed surface 21a of the wiring layer 21 can be flush with or lower than the first surface 23a of the insulating layer 23.

The electronic components 22 and 25 are embedded in the insulating layer 23 and electrically connected to the wiring layer 21. For instance, the electronic components 22 and 25 can be active elements, passive elements, or a combination thereof. In an embodiment, the package structures 3 and 3′ have a plurality of electronic components 22 and 25, and the electronic components 22 and 25 are independent and electrically isolated from each other.

In an embodiment, the wiring layer 21 has a plurality of conductive pads 210 and a plurality of conductive traces 211, and the conductive pads 210 are bonded and electrically connected to the electronic components 22, 25.

In an embodiment, each of the package structures 2, 2′, 3 and 3′ further has a plurality of conductive elements 24 formed on the first surface 23a of the insulating layer 23 and electrically connected to the wiring layer 21.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A package structure, comprising:
an insulating layer having a first surface and a second surface opposite to the first surface;
a wiring layer formed in the insulating layer by electroplating and having a surface exposed from the first surface of the insulating layer; and
at least one electronic component embedded in the insulating layer and electrically connected to the wiring layer.

2. The package structure of claim 1, wherein the wiring layer is embedded in the first surface of the insulating layer.

3. The package structure of claim 1, wherein the surface of the wiring layer exposed from the first surface of the insulating layer is flush with or lower than the first surface of the insulating layer.

4. The package structure of claim 1, wherein the wiring layer comprises a plurality of conductive traces, and a plurality of conductive pads bonded and electrically connected to the electronic component.

5. The package structure of claim 1, wherein the electronic component is an active element, a passive element, or a combination thereof.

6. The package structure of claim 1, further comprising a plurality of conductive elements formed on the first surface of the insulating layer and electrically connected to the wiring layer.

7. The package structure of claim 1, wherein the insulating layer is made of a molding compound, a primer or a dielectric material.

8. The package structure of claim 1, further comprising another electronic component that is independent from and electrically isolated from the at least one electronic component.

9. A method of fabricating a package structure, comprising the steps of:
forming a wiring layer on a carrier by electroplating;
disposing at least one electronic component on the wiring layer, and electrically connecting the electronic component to the wiring layer;
forming on the carrier an insulating layer that encapsulates the wiring layer and the electronic component and a first surface bonded to the carrier and a second surface opposite to the first surface; and
removing the carrier to expose the wiring layer and the first surface of the insulating layer.

10. The method of claim 9, wherein the wiring layer has a surface flush with or lower than the first surface of the insulating layer.

11. The method of claim 9, wherein the wiring layer comprises a plurality of conductive traces, and a plurality of conductive pads bonded and electrically connected to the electronic component.

12. The method of claim 9, wherein the electronic component is an active element, a passive element, or a combination thereof.

13. The method of claim 9, further comprising forming a plurality of conductive elements on the first surface of the insulating layer, and electrically connecting the conductive elements to the wiring layer.

14. The method of claim 9, wherein the insulating layer is made of a molding compound, a primer or a dielectric material.

15. The method of claim 9, further comprising disposing on the wiring layer another electronic component that is independent from and electrically isolated from the at least one electronic component.
